(19) United States
(12) Patent Application Publication
(10) Pub. No.: US 2025/0379576 A1
(43) Pub. Date: Dec. 11, 2025

(54) HYBRID SWITCH CELL SCHEME

(71) Applicant: QUALCOMM Incorporated, San Diego, CA (US)

(72) Inventors: Anand Ashok BALIGATTI, Bangalore (IN); Giby SAMSON, San Diego, CA (US); Ankur MEHROTRA, Greater Noida (IN); Ishant BHATIA, Fatehabad (IN); Kuldeep Singh CHAHAL, Noida (IN); Kamesh MEDISETTI, Bangalore (IN); Smeeta HEGGOND, Bagalkot (IN); Amitabh GOYAL, Bangalore (IN); Siddesh HALAVARTHI MATH REVANA, Bangalore (IN)

(21) Appl. No.: 18/738,247

(22) Filed: Jun. 10, 2024

(51) Int. Cl. H03K 17/687

(52) U.S. Cl. CPC H03K 17/6871

(57) ABSTRACT

A chip includes a circuit block. globally distributed switches physically located in the circuit block, and micro switches distributed between at least two of the globally distributed switches in the circuit block.

### BACKGROUND

### Field

Aspects of the present disclosure relate generally to power management, and more particularly, to power gating.

### Background

Circuit blocks on a chip (e.g., system on a chip (SoC)) receive power from a power source (e.g., a battery or another power source). The chip may employ power gating to reduce power consumption by gating power (i.e., switching off power) to a circuit block on the chip when the circuit block is inactive (i.e., not in use). To implement power gating, the chip may include one or more switches coupled between the power source and the circuit block. To gate power to the circuit block when the circuit block is inactive, a power manager turns off the one or more switches. This prevents leakage current from flowing through the circuit block when the circuit block is inactive, which significantly reduces power consumption due to leakage current.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

An aspect relates to a chip. The chip includes a circuit block, globally distributed switches physically located in the circuit block, and micro switches distributed between at least two of the globally distributed switches in the circuit block.

A second aspect relates to a chip. The chip includes a circuit block, block switches arranged along at least part of a periphery of the circuit block, globally distributed switches physically located in the circuit block, and a gated network coupled to the circuit block, the block switches, and the globally distributed switches.

A third aspect relates to a chip. The chip includes a circuit block, block switches arranged along at least part of a periphery of the circuit block, globally distributed switches physically located in the circuit block, a first gated network coupled to the circuit block and the block switches, and a second gated network coupled to the circuit block and the globally distributed switches.

### BRIEF DESCRIPTION OF THE DRAWINGS

FIG. 1 shows an example of a head switch for power gating according to certain aspects of the present disclosure.

FIG. 2 shows an example of a foot switch for power gating according to certain aspects of the present disclosure.

FIG. 3A shows a top view of an example of globally distributed switches distributed in a circuit block according to certain aspects of the present disclosure.

FIG. 3B shows an example of a first network coupled to the globally distributed switches of FIG. 3A according to certain aspects of the present disclosure.

FIG. 3C shows an example of a second network coupled to the globally distributed switches of FIG. 3A according to certain aspects of the present disclosure.

FIG. 4 shows an example of circuitry for controlling the globally distributed switches of FIGS. 3A to 3C according to certain aspects of the present disclosure.

FIG. 5 shows a top view of an example of micro switches according to certain aspects of the present disclosure.

FIG. 6A shows an exemplary layout of cells in the circuit block with empty spaces according to certain aspects of the present disclosure.

FIG. 6B shows an example in which the micro switches are placed in the empty spaces of FIG. 6A according to certain aspects of the present disclosure.

FIG. 7 shows an example in which the micro switches are coupled in a star configuration for receiving an enable signal according to certain aspects of the present disclosure.

FIG. 8 shows another example in which the micro switches are coupled in a star configuration for receiving an enable signal according to certain aspects of the present disclosure.

FIG. 9 shows an example in which the micro switches are coupled in a daisy chain for receiving an enable signal according to certain aspects of the present disclosure.

FIG. 10A shows a top view of an example of block switches arranged along a periphery of a circuit block according to certain aspects of the present disclosure.

FIG. 10B shows an example of networks coupled to the block switches of FIG. 10A according to certain aspects of the present disclosure.

FIG. 11A shows an example of circuitry for controlling the block switches of FIGS. 10A and 10B according to certain aspects of the present disclosure.

FIG. 11B shows another example of circuitry for controlling the block switches of FIGS. 10A and 10B according to certain aspects of the present disclosure.

FIG. 12A shows an example of a hybrid power gating scheme including block switches and globally distributed switches according to certain aspects of the present disclosure.

FIG. 12B shows an example in which the block switches and the globally distributed switches of FIG. 12A are coupled to a shared gated network according to certain aspects.

FIG. 12C shows an example in which the globally distributed switches are distributed throughout the circuit block according to certain aspects.

FIG. 12D shows an example in which the block switches and the globally distributed switches of FIG. 12A are coupled to independent gated networks according to certain aspects.

FIG. 13 shows an example of the hybrid power gating scheme further including micro switches according to certain aspects of the present disclosure.

FIG. 14A shows another example of the hybrid power gating scheme according to certain aspects of the present disclosure.

FIG. 14B shows an example in which globally distributed switches and block switches share a gated network according to certain aspects of the present disclosure.

FIG. 15A shows an example of a control system for controlling block switches and globally distributed switches according to certain aspects of the present disclosure.

FIG. 15B shows another example of a control system for controlling block switches and globally distributed switches according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

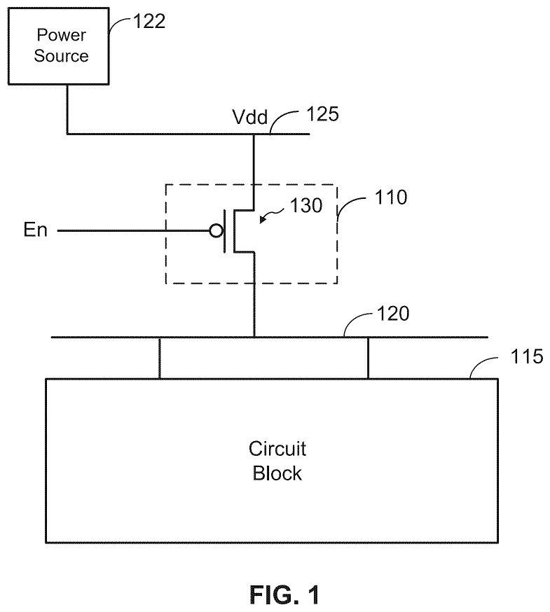

Circuit blocks on a chip (e.g., system on a chip (SoC)) receive power from a power source (e.g., a battery or another power source). The chip may employ power gating to reduce power consumption by gating power (i.e., switching off power) to a circuit block on the chip when the circuit block is inactive (i.e., not in use). In this regard, FIG. 1 shows an example of a switch 110 (also referred to as a power switch) for power gating a circuit block 115. Although one switch is shown in FIG. 1 for simplicity, it is to be appreciated that multiple switches may be used to gate power to the circuit block 115, as discussed further below.

In the example in FIG. 1, the switch 110 is implemented with a head switch coupled between a first power network 120 and a second power network 125. However, it is to be appreciated that the present disclosure is not limited to this example. In other implementations, the switch 110 may be implemented with a foot switch, as discussed further below.

Each of the power networks 120 and 125 may include one or more voltage supply rails. Although each of the power networks 120 and 125 is depicted as a line in FIG. 1 for case of illustration, it is to be appreciated that each of the power networks 120 and 125 may have a two-dimensional structure or a three-dimensional structure to distribute power over an area of the chip. A power network with a two-dimensional structure or a three-dimensional structure may also be referred to as a power mesh, a power grid, or another term.

In this example, the second power network 125 is coupled to a power source 122 to receive power from the power source 122. The power source 122 may include a battery, one or more voltage regulators (e.g., a switching regulator and/or a low dropout (LDO) regulator), a power management integrated circuit (PMIC), or any combination thereof. The power source 150 may be integrated on the chip or may be located off chip. The power source 150 provides the first power network 120 with a supply voltage Vdd.

The circuit block 115 is coupled to the first power network 120 for receiving power. The circuit block 115 may include a memory, a processor (a central processing unit (CPU)), logic gates, or any combination thereof. The circuit block 115 may be coupled to the first power network 120 at multiple locations (e.g., using vias) to distribute power to various portions of the circuit block 115. For case of illustration, the ground connections for the circuit block 115 are not shown in FIG. 1.

In this example, the on/off state of the switch 110 is controlled by an enable signal En from a power manager (not shown) or a switch controller under the control of the power manager. In the example in FIG. 1, the switch 110 includes a p-type field effect transistor (PFET) 130 having a source coupled to the second power network 125, a drain coupled to the first power network 120, and a gate configured to receive the enable signal En. It is to be appreciated that the PFET 130 may be physically implemented on the chip with multiple PFETs coupled in parallel. In this example, the switch 110 turns on when the enable signal En is low (e.g., ground potential). However, it is to be appreciated that the present disclosure is not limited to this example.

In this example, the power manager (not shown) turns on the switch 110 using the enable signal En when the circuit block 115 is active. This allows the power source 122 to provide power to the circuit block 115 through the switch 110. The power manager turns off the switch 110 when the circuit block 115 is inactive (i.e., not in use). In this case, the first power network 120 is power collapsed, which significantly reduces leakage current.

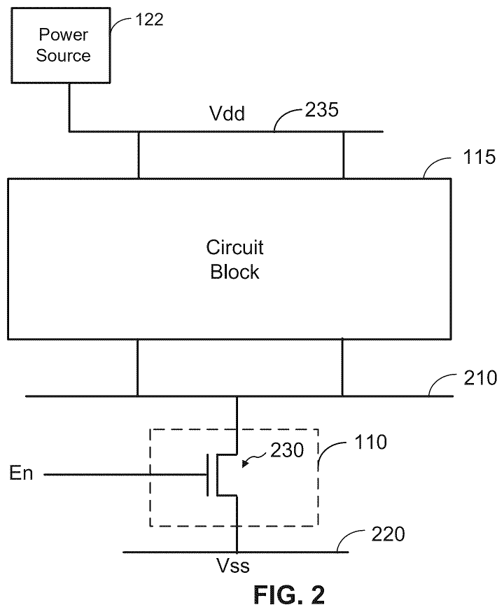

FIG. 2 shows an example in which the switch 110 is implemented with a foot switch. In this example, the power network 235 is coupled to the circuit block 115 to provide power to the circuit block 115 from the power source 122. Also, in this example, the switch 110 is coupled between a first ground network 210 and a second ground network 220, in which the first ground network 210 is coupled to the circuit block 115 and the second ground network 220 is coupled to a ground (e.g., an external ground). Although each of the ground networks 210 and 220 is depicted as a line in FIG. 2 for ease of illustration, it is to be appreciated that each of the ground networks 210 and 220 may have a two-dimensional structure or a three-dimensional structure.

In this example, the on/off state of the switch 110 is controlled by the enable signal En from a power manager (not shown) or a switch controller under the control of the power manager. In the example in FIG. 2, the switch 110 includes a n-type field effect transistor (NFET) 230 having a source coupled to the second ground network 220, a drain coupled to the first ground network 210, and a gate configured to receive the enable signal En. It is to be appreciated that the NFET 230 may be physically implemented on the chip with multiple NFETs coupled in parallel. In this example, the switch 110 turns on when the enable signal En is high (e.g., supply voltage).

In this example, the power manager (not shown) turns on the switch 110 using the enable signal En when the circuit block 115 is active. This couples the circuit block 115 to the ground, which allows current to flow through the circuit block 115. The power manager turns off the switch 110 when the circuit block 115 is inactive (i.e., not in use). In this case, the circuit block 115 is decoupled from the ground, which significantly reduces leakage current.

Thus, the switch 110 may be implemented with a head switch or a foot switch. Accordingly, it is to be appreciated that aspects of the present disclosure may be applied to head switches and foot switches.

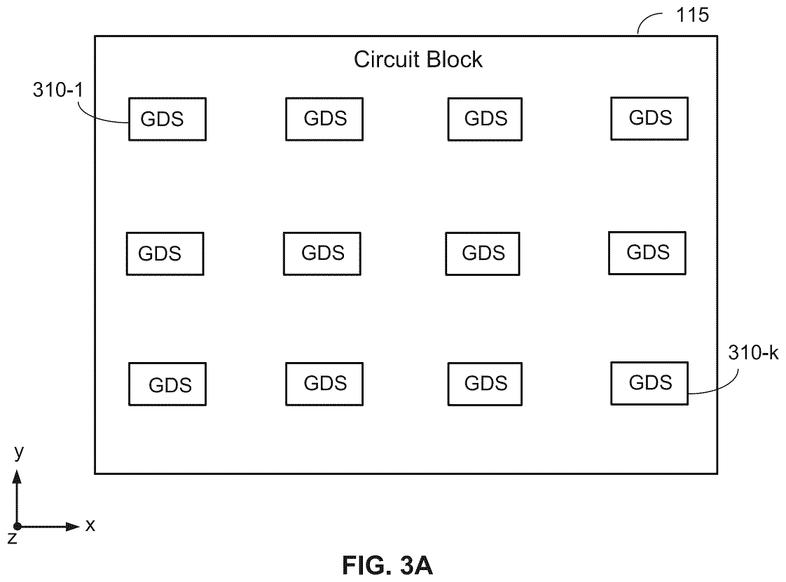

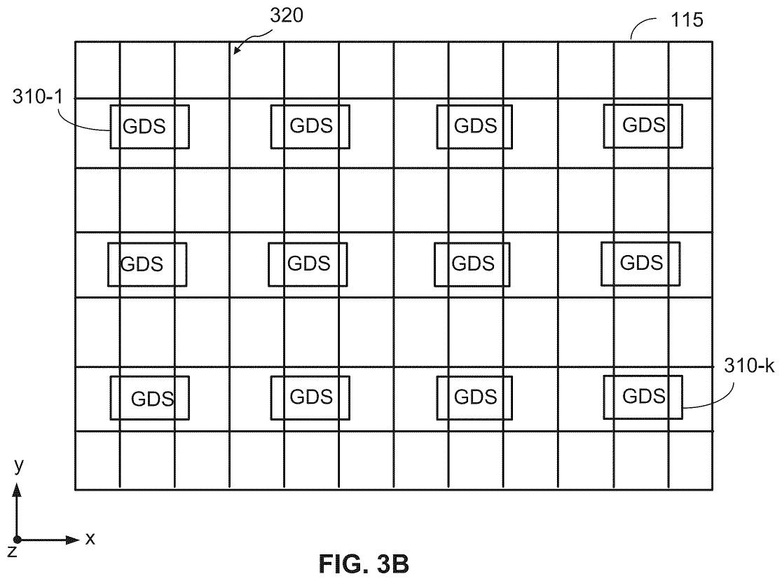

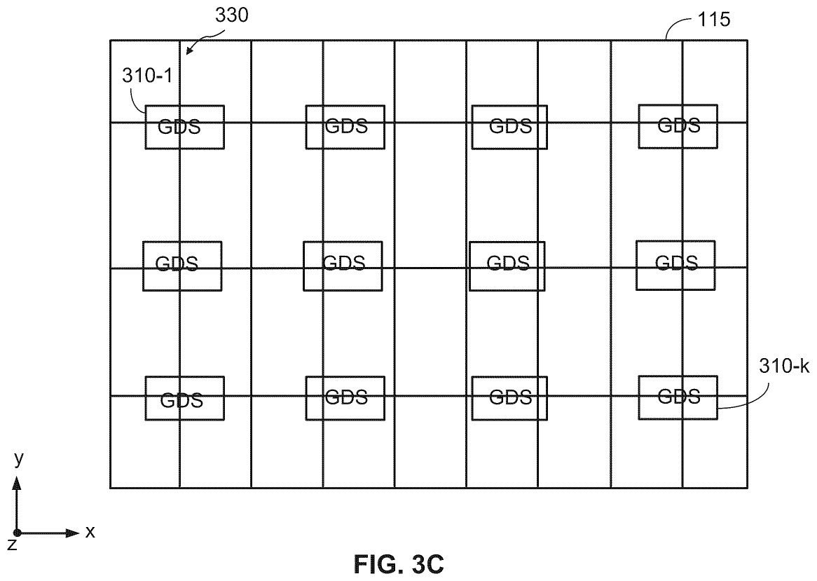

As discussed above, the chip may include multiple switches for power gating the circuit block 115. In this regard, FIG. 3A shows a top view of an example of globally distributed switches 310-1 to 310-k distributed in the circuit block 115 for gating power to the circuit block 115 according to certain aspects. The globally distributed switches 310-1 to 310-k may be physically located in the circuit block 115. In FIG. 3A, the globally distributed switches 310-1 to 310-k are depicted as boxes labeled “GDS”. For the example where the globally distributed switches 310-1 to 310-k are implemented with head switches, the globally distributed switches 310-1 to 310-k may also be referred to as globally distributed head switches (GDHS).

In certain aspects, the globally distributed switches 310-1 to 310-k may be included in globally distributed switch (GDS) cells that are distributed in the circuit block 115 to provide power gating (i.e., power switching). In this example, the physical layout of a GDS cell may be defined in a cell library. For the example where the globally distributed switches 310-1 to 310-k are implemented with head switches, a GDS cell may also be referred to as a GDHS cell. A GDS cell may also include one or more buffers and/or other devices.

FIG. 3A shows an example in which the globally distributed switches 310-1 to 310-k are distributed in the circuit block 115 in a regular pattern. However, it is to be appreciated that the present disclosure is not limited to this example. Accordingly, it is to be appreciated that the present disclosure is not limited to a particular distribution pattern. Also, it is to be appreciated that the chip may include a larger number of the globally distributed switches 310-1 to 310-k than shown in FIG. 3A.

FIGS. 3B and 3C shows an example of a first network 320 (shown in FIG. 3B) and a second network 330 (shown in FIG. 3C), in which the globally distributed switches 310-1 to 310-k are coupled between the first network 320 and the second network 330. Note that the first network 320 and the second network 330 are shown separately in FIG. 3B and FIG. 3C, respectively, for case of illustration.

The first network 320 is coupled to the circuit block 115. The second network 330 may be a power network (e.g., power network 125) coupled to a power source (e.g., power source 122) or a ground network (e.g., the ground network 220). For example, when the globally distributed switches 310-1 to 310-k are implemented with head switches (e.g., PFETs), the second network 330 may be a power network. When the globally distributed switches 310-1 to 310-k are implemented with foot switches (e.g., NFETs), the second network 330 may be a ground network. The first network 320 may also be referred to as a gated network since the first network 320 is selectively gated by the globally distributed switches 310-1 to 310-k.

It is to be appreciated that the layout of the first network 320 shown in FIG. 3B is for illustrative purposes, and that the first network 320 is not limited to a particular layout. Also, it is to be appreciated that the layout of the second network 330 shown in FIG. 3C is for illustrative purposes, and that the second network 330 is not limited to a particular layout. In certain aspects, the second network 330 may include metal interconnects and vias stacked vertically (i.e., z direction) in the chip to couple the second network 330 to bumps (not shown) on top of the chip, in which the bumps (e.g., solder bumps) are coupled to an external power source (e.g., power source 122) or an external ground.

In this example, the on/off states of the globally distributed switches 310-1 to 310-k may be controlled by a power manager (not shown) or a switch controller under the control of the power manager. For example, the power manager (not shown) may turn on the globally distributed switches 310-1 to 310-k when the circuit block 115 is active. The power manager may turn off the globally distributed switches 310-1 to 310-k when the circuit block 115 is inactive (i.e., not in use) to reduce leakage current.

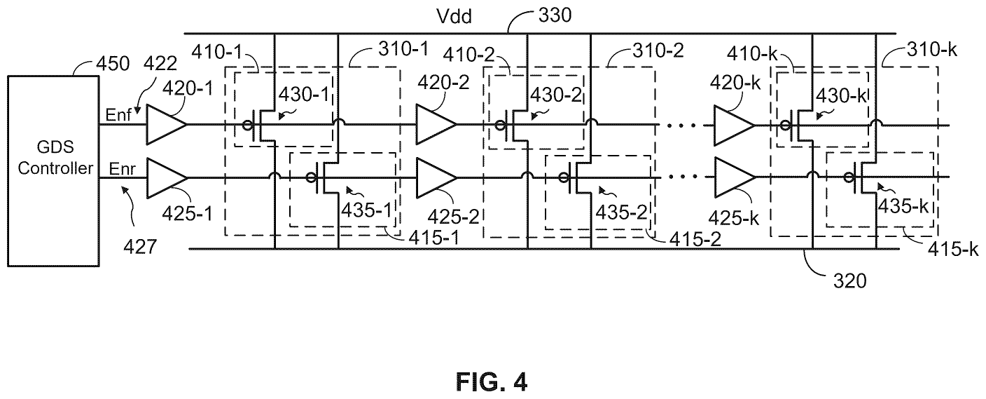

FIG. 4 shows an example of circuitry for enabling the globally distributed switches 310-1 to 310-k according to certain aspects. Note that the circuit block 115 is not shown in FIG. 4 and the networks 320 and 330 are depicted as lines in FIG. 4 for case of illustration. Also, the globally distributed switches 310-1 to 310-k are shown arranged in a row in FIG. 4 for case of illustration (i.e., FIG. 4 is not intended to depict the physical layout of the globally distributed switches 310-1 to 310-k on the chip).

In this example, the circuitry includes a globally distributed switch controller 450, a first enable path 422, and a second enable path 427. The globally distributed switch controller 450 may be coupled to the power manager discussed above.

In this example, each of the globally distributed switches 310-1 to 310-k may include a respective high-resistance switch 410-1 to 410-k to mitigate inrush current and a respective low-resistance switch 415-1 to 415-k to provide low current-resistance (IR) drop across the switch when the circuit block 115 is active. Each of the high-resistance switches 410-1 to 410-k may have a higher on resistance than each of the low-resistance switches 415-1 to 415-k. In this example, each of the low-resistance switches 415-1 to 415-k may be larger than each of the high-resistance switches 410-1 to 410-k. The high-resistance switches 410-1 to 410-k may also be referred to as the few switches and the low-resistance switches 415-1 to 415-k may also be referred to as the rest switches.

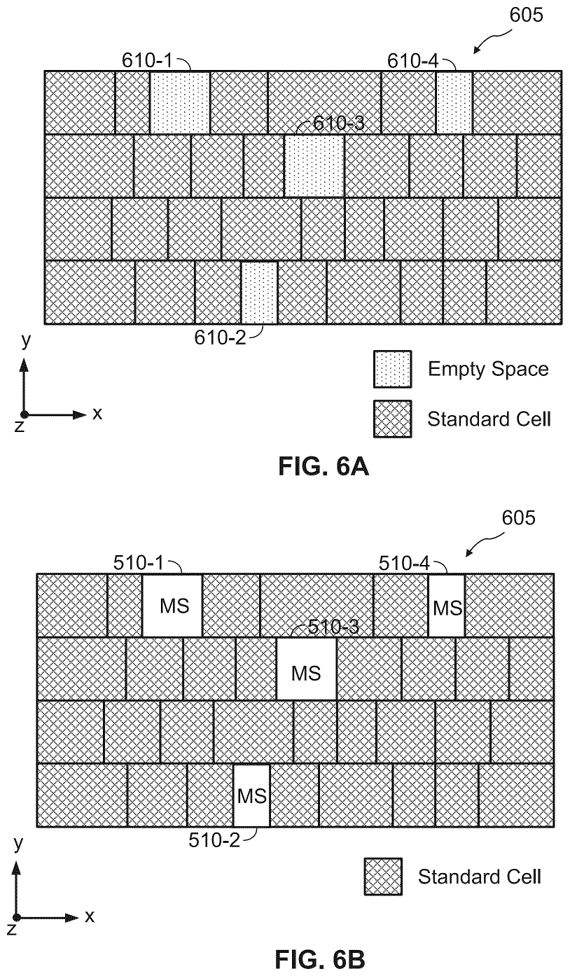

In the example shown in FIG. 6, each of the high-resistance switches 410-1 to 410-k is implemented with a respective PFET 430-1 to 430-k, and each of the low-resistance switches 415-1 to 415-k is implemented with a respective PFET 435-1 to 435-k. In this example, the networks 330 and 320 may be power networks. However, it is to be appreciated that the globally distributed switches 310-1 to 310-k are not limited to this example. In other implementations, each of the high-resistance switches 410-1 to 410-k may be implemented with a respective NFET, and each of the low-resistance switches 415-1 to 415-k is implemented with a respective NFET. In this example, the networks 330 and 320 may be ground networks.

In this example, the first enable path 422 is coupled to the globally distributed switch controller 450 and includes buffers 420-1 to 420-k. Each of the buffers 420-1 to 420-k may include one or more inverters. The first enable path 422 is coupled to the high-resistance switches 410-1 to 410-k in a daisy chain. In this example, the buffers 420-1 to 420-k are located between the high-resistance switches 410-1 to 410-k, which produces delays between the high-resistance switches 410-1 to 410-k. The delays between the high-resistance switches 410-1 to 410-k cause the high-resistance switches 410-1 to 410-k to sequentially turn on during power up, as discussed further below. In the example shown in FIG. 4, the first enable path 422 is coupled to the gates of the PFETs 430-1 to 430-k.

In this example, the second enable path 427 is coupled to the globally distributed switch controller 450 and includes buffers 425-1 to 425-k. Each of the buffers 425-1 to 425-k may include one or more inverters. The second enable path 427 is coupled to the low-resistance switches 415-1 to 415-k in a daisy chain. In this example, the buffers 425-1 to 425-k are located between the low-resistance switches 415-1 to 415-k, which produces delays between the low-resistance switches 415-1 to 415-k. The delays between the low-resistance switches 415-1 to 415-k cause the low-resistance switches 415-1 to 415-k to sequentially turn on during power up, as discussed further below. In the example shown in FIG. 4, the second enable path 427 is coupled to the gates of the PFETs 435-1 to 435-k.

To power up the circuit block 115 from a power collapsed state, the globally distributed switch controller 450 may first turn on the high-resistance switches 410-1 to 410-k (i.e., the few switches) to mitigate inrush current by outputting a first enable signal Enf to the first enable path 422. The first enable signal Enf may be low (e.g., ground potential) or high (e.g., Vdd) depending, for example, on whether the high-resistance switches 410-1 to 410-k are implemented with PFETs or NFETs. The first enable signal Enf propagates through the first enable path 422, causing the high-resistance switches 410-1 to 410-k to turn on. In this example, the delays between the high-resistance switches 410-1 to 410-k due to the buffers 420-1 to 420-k cause the high-resistance switches 410-1 to 410-k to sequentially turn on as the first enable signal Enf propagates through the first enable path 422. In certain aspects, the first enable path 422 may loop back to the globally distributed switch controller 450 to enable the globally distributed switch controller 450 to detect when the high-resistance switches 410-1 to 410-k are turned on by detecting the return of the first enable signal Enf.

After the high-resistance switches 410-1 to 410-k are turned on, the globally distributed switch controller 450 turns on the low-resistance switches 415 to 415-k (e.g., the rest switches) by outputting a second enable signal Enr to the second enable path 427. The second enable signal Enr may be low (e.g., ground potential) or high (e.g., Vdd) depending, for example, on whether the low-resistance switches 415-1 to 415-k are implemented with PFETs or NFETs. The second enable signal Enr propagates through the second enable path 427, causing the low-resistance switches 415-1 to 415-k to turn on. In this example, the delays between the low-resistance switches 415-1 to 415-k due to the buffers 425-1 to 425-k cause the low-resistance switches 415-1 to 415-k to sequentially turn on as the second enable signal Enr propagates through the second enable path 427.

During power down, the globally distributed switch controller 450 may turn off the globally distributed switches 310-1 to 310-k to power collapse the circuit block 115. For example, the globally distributed switch controller 650 may turn off the globally distributed switches 310-1 to 310-k by outputting a logic state to the enable paths 422 and 427 that is the inverse of the logic state of the enable signals Enf and Enr used to turn on the globally distributed switches 310-1 to 310-k.

It is to be appreciated that, in some implementations, the high-resistance switches 410-1 to 410-k may be omitted from the globally distributed switches 310-1 to 310-k. In these implementations, the chip may employ other techniques to mitigate inrush current.

In advanced processes, the widths of the metal rails in the network 320 continue to shrink, resulting in higher metal resistances in the network 320. The higher resistances in the network 320 lead to larger IR drops in the network 320, which reduces the operating voltages of active devices in the circuit block 115. The reduction in the operating voltages of the active devices degrade the performance (e.g., speed) of the active devices.

One approach to reduce IR drops in the network 320 is to decrease the pitch (i.e., distance) between the rails in the network 320. However, this approach increases metal congestion in the chip and makes standard cell placement in the circuit block 115 more challenging. Another approach is to increase the number of globally distributed switches and reduce the spacing between the globally distributed switches. However, this approach increases metal congestion and may reduce the area available for standard cells in the circuit block 115 (i.e., reduce standard cell utilization area).

To address the above, aspects of the present disclosure provide micro switches that may be sprinkled in the circuit block 115 between the globally distributed switches to reduce IR drops. For example, one or more micro switches may be located at or close to a local hotspot of the circuit block 115 to reduce the IR drops for active devices in the local hotspot. A hotspot may be an area of the circuit block 115 with a large current density due to, for example, high switching activity in the area and/or a dense cluster of active devices in the area. The above features and other features of the present disclosure are discussed further below.

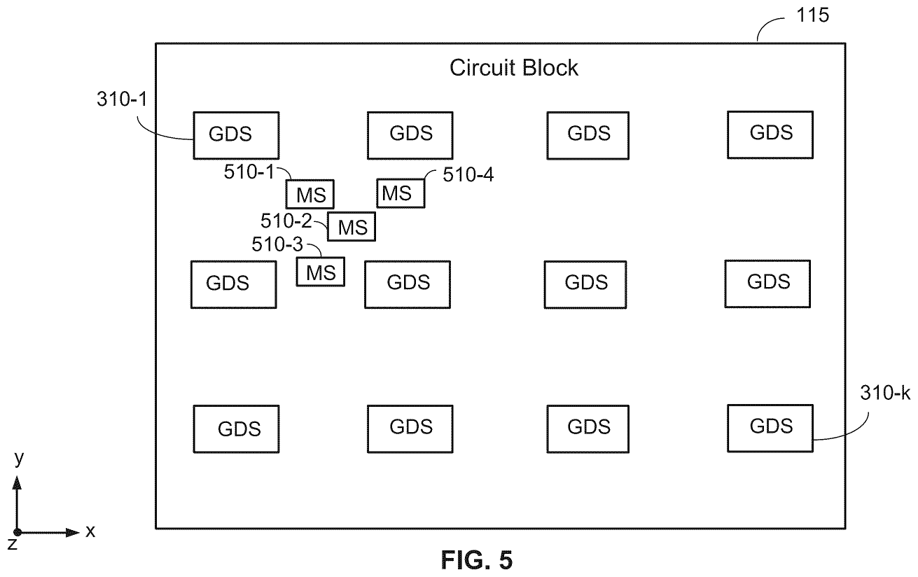

FIG. 5 shows a top view of the globally distributed switches 310-1 to 310-k distributed in the circuit block 115. FIG. 5 also shows an example of micro switches 510-1 to 510-4 sprinkled (i.e., distributed) between at least two of the globally distributed switches 310-1 to 310-k. For example, the micro switches 510-1 to 510-4 may be sprinkled in a local hot spot of the circuit block 115 to reduce IR drops for the local hot spot. In FIG. 5, the micro switches 510-1 to 510-4 are depicted as boxes labeled “MS”. Each of the micro switches 510-1 to 510-4 may be implemented with a head switch (e.g., a PFET) or a foot switch (e.g., NFET). It is to be appreciated that the chip may include additional micro switches (not shown) sprinkled in other areas of the chip. In the example in FIG. 5, the distribution of the micro switches 510-1 to 510-4 is nonuniform, and may depend, for example, on areas in the circuit block 115 that are available for placement of the micro switches 510-1 to 510-4 (i.e., areas not occupied by standard cells with active devices).

In the example shown in FIG. 5, the minimum spacing between the micro switches 510-1 to 510-4 (i.e., the smallest spacing between adjacent micro switches) is less than the minimum spacing between the globally distributed switches 310-1 to 310-k (i.e., the smallest spacing between adjacent globally distributed switches).

In certain aspects, each of the micro switches 510-1 to 510-4 may be coupled between the second network 330 (shown in FIG. 3C) and the first network 320 (shown in FIG. 3B). In some implementations, the micro switches 510-1 to 510-4 may be coupled between the second network 330 and the circuit block 115 through lower-level metal layers.

The micro switches 510-1 to 510-4 are smaller in size (e.g., chip area) than the globally distributed switches 310-1 to 310-k. For example, each of the micro switches 510-1 to 510-4 may be at least two times smaller (i.e., at least 50 percent smaller) than each of the globally distributed switches 310-1 to 310-k. In some implementations, the micro switches 510-1 to 510-4 may have varying sizes. For example, the micro switches 510-1 to 510-4 may have varying sizes to fit into empty spaces of varying sizes in the circuit block 115.

In this regard, FIG. 6A shows an exemplary layout 605 of standard cells for a portion of the circuit block 115. In this example, each of the standard cells may include one or more transistors that are arranged to implement a circuit (e.g., an inverter, a driver, a logic gate, combinational logic, a latch, a flip-flop, a bit cell, or another type of circuit). The layout of each standard cell is specified (i.e., defined) in a standard cell library, which may be stored in a memory. The standard cell library may specify (i.e., define) the layout of each one of various standard cells that can be placed (i.e., laid out) in the circuit block 115 for a particular process. The circuit block 115 may include multiple instances of a particular standard cell defined in the standard cell library. The layout of each standard cell defined in the standard cell library may include the layout of gates, diffusion regions, and contacts in the cell. As used herein, a “standard cell” is a cell that is defined in a standard cell library.

In the example in FIG. 6A, the standard cells are arranged in rows and may have varying widths in the x direction. However, it is to be appreciated that the present disclosure is not limited to this example. In this example, the layout 605 includes empty spaces 610-1 to 610-4 between the standard cells. The empty spaces 610-1 to 610-4 may have varying sizes (e.g., depending on the sizes of the standard cells and the placement of the standard cells in the rows). In this example, the empty spaces 610-1 and 610-3 have wider widths in the x direction than the empty spaces 610-2 and 610-4. However, it is to be appreciated that the present disclosure is not limited to this example.

FIG. 6B shows an example in which the micro switches 510-1 to 510-4 are placed in the empty spaces 610-1 to 610-4 in the layout 605 to take advantage of the empty spaces 610-1 to 610-4. In this example, the micro switches 510-1 to 510-4 may have varying sizes corresponding to the varying sizes of the empty spaces 610-1 to 610-4. For example, the micro switches 510-1 and 510-3 may be larger than the micro switches 510-2 and 510-4 since the empty spaces 610-1 and 610-3 corresponding to the micro switches 510-1 and 510-3 are larger than the empty spaces 610-2 and 610-4 corresponding to the micro switches 510-2 and 510-4.

It is to be appreciated that the present disclosure is not limited to the example shown in FIG. 6B. For example, in some implementations, a micro switch may span two or more rows in the y direction.

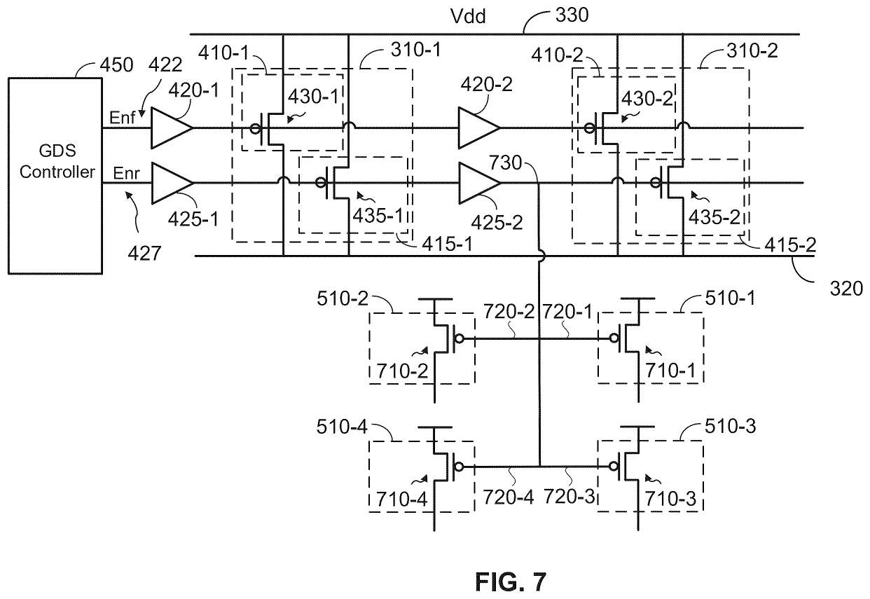

In certain aspects, the on/off states of the micro switches 510-1 to 510-4 may be controlled by the globally distributed switch controller 450. In this regard, FIG. 7 shows an exemplary configuration for controlling the micro switches 510-1 to 510-4 according to certain aspects. In this example, the micro switches 510-1 to 510-4 are coupled to the second enable path 427 for the low-resistance switches 415-1 to 415-k (i.e., rest switches) in a star configuration (also referred to as a star topology). In the example in FIG. 7, the micro switches 510-1 to 510-4 are coupled the second enable path 427 through respective branches 720-1 to 720-4 coupled to a common node 730 on the second enable path 427.

In the example in FIG. 7, each of the micro switches 510-1 to 510-4 is implemented with a respective PFET 710-1 to 710-4 having a gate coupled to the second enable path 427 (e.g., between the buffer 425-2 and the low-resistance switch 415-2). However, it is to be appreciated that, in other implementations, each of the micro switches 510-1 to 510-4 may be implemented with a respective NFET.

In this example, the micro switches 510-1 to 510-4 turn on when the globally distributed switch controller 450 outputs the second enable signal Enr to the second enable path 427 and the second enable signal Enr propagates from the second enable path 427 to the micro switches 510-1 to 510-4 (e.g., to the gates of the PFETs 710-1 to 710-4). Thus, in this example, the globally distributed switch controller 450 uses the second enable signal Enr to turn on both the low-resistance switches 415-1 to 415-n and the micro switches 510-1 to 510-4.

In this example, the micro switches 510-1 to 510-4 are enabled after the high-resistance switch 410-1 to 410-k in the globally distributed switches 310-1 to 310-k are turned on to mitigate inrush current. Thus, in this example, the micro switches 510-1 to 510-4 do not need high-resistances switches for inrush mitigation.

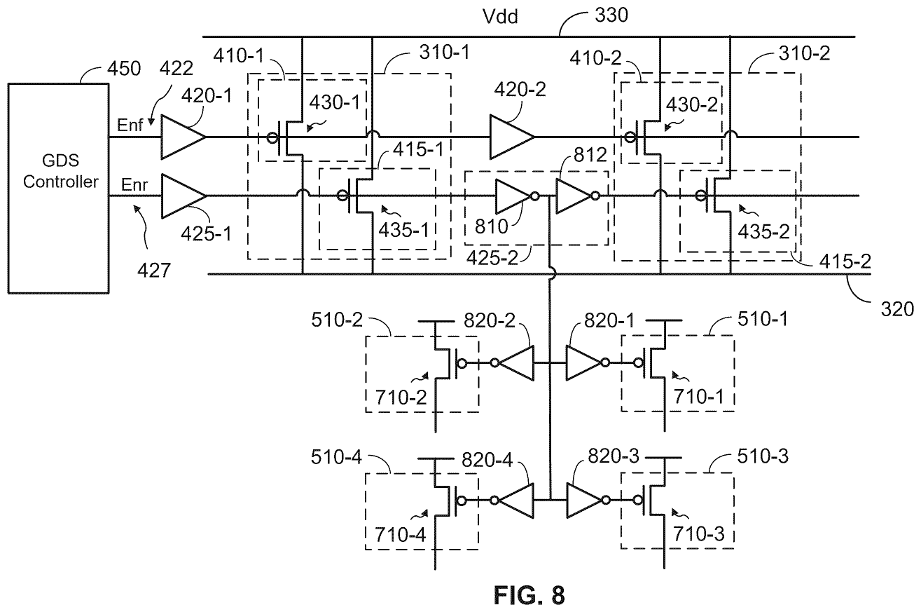

FIG. 8 shows another exemplary configuration in which the micro switches 510-1 to 510-4 are coupled to the second enable path 427 in a star configuration. In this example, the buffer 425-2 includes inverters 810 and 812 coupled in series. The chip also includes inverters 820-1 to 820-4 in which the input of each of the inverters 820-1 to 820-4 is coupled between the inverters 810 and 812, and the output of each of the inverters 820-1 to 820-4 is coupled to a respective one of the micro switches 510-1 to 510-4 (e.g., the gate of a respective one of the PFETs 710-1 to 710-4).

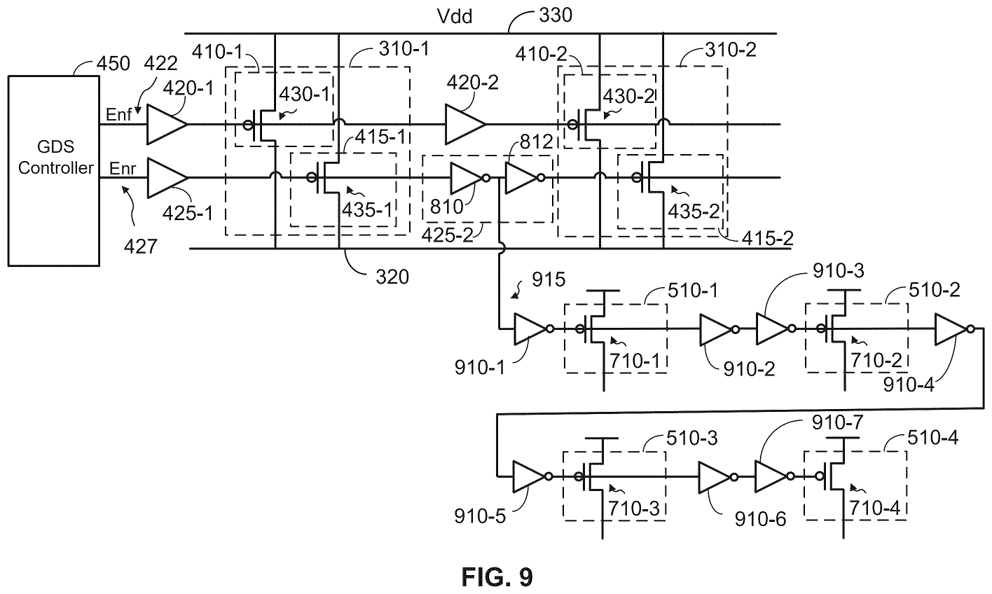

FIG. 9 shows an exemplary configuration in which the micro switches 510-1 to 510-4 are coupled to the second enable path 427 in a daisy chain configuration. In this example, the buffer 425-2 includes the inverters 810 and 812 discussed above. Also, in this example, the chip includes a third enable path 915 coupled between the inverters 810 and 812. The third enable path 915 couples the micro switches 510-1 to 510-4 in a daisy chain and includes inverters 910-1 to 910-7. The input of the inverter 910-1 is coupled between the inverters 810 and 812, and the output of the inverter 910-1 is coupled to the micro switch 510-1 (e.g., the gate of the respective PFET 710-1). The inverters 910-2 and 910-3 are coupled in series between the micro switches 510-1 and 510-2, the inverters 910-4 and 910-5 are coupled in series between the micro switches 510-2 and 510-3, and the inverters 910-6 and 910-7 are coupled in series between the micro switches 510-3 and 510-4.

In this example, when the globally distributed switch controller 450 outputs the second enable signal Enr to the second enable path 427, the second enable signal Enr propagates to the third enable path 915 (which is coupled between the globally distributed switches 310-1 and 310-2 in this example). When the second enable signal Enr reaches the third enable path 915, the second enable signal Enr propagates through the third enable path 915 and sequentially turns on the micro switches 510-1 to 510-4.

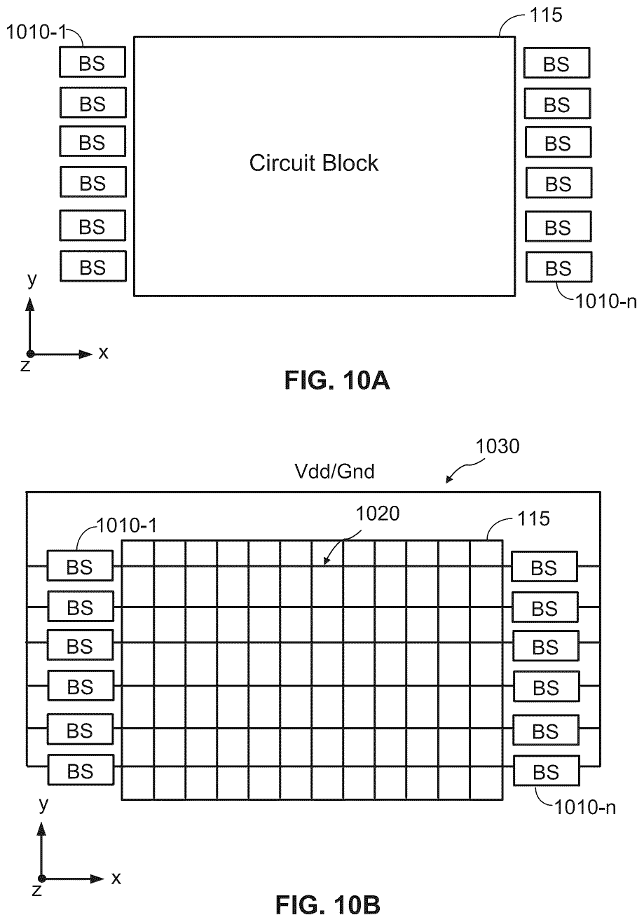

Power gating may also be performed using block switches. In this regard, FIG. 10A shows a top view of an example of block switches 1010-1 to 1010-n arranged along a periphery of the circuit block 115 for gating power to the circuit block 115 according to certain aspects. In FIG. 10A, the block switches 1010-1 to 1010-n are depicted as boxes labeled “BS”. For the example where the block switches 1010-1 to 1010-n are implemented with head switches, the block switches 1010-1 to 1010-n may also be referred to as block head switches (BHS). It is to be appreciated that the chip may include a larger number of the block switches 1010-1 to 1010-n than shown in FIG. 10A.

Although FIG. 10A shows an example in which the block switches 1010-1 to 1010-n are arranged along the left boundary and the right boundary of the circuit block 115, it is to be appreciated that the block switches 1010-1 to 1010-n may also be arranged along the top boundary and/or the bottom boundary of the circuit block 115 in FIG. 10A. Thus, the block switches 1010-1 to 1010-n are arranged along at least part of the periphery of the circuit block 115.

Although the circuit block 115 is shown having a rectangular shape in the example in FIG. 10A, it is to be appreciated that the circuit block 115 may have another shape. Accordingly, it is to be understood that the circuit block 115 is not limited to a particular shape.

FIG. 10B shows an example of a first network 1020 and a second network 1030, in which the block switches 1010-1 to 1010-n are coupled between the first network 1020 and the second network 1030. The first network 1020 is coupled to the circuit block 115. The second network 1030 may be a power network (e.g., power network 125) coupled to a power source (e.g., power source 122) or a ground network (e.g., the ground network 220). For example, when the block switches 1010-1 to 1010-n are implemented with head switches (e.g., PFETs), the second network 1030 may be a power network. When the block switches 1010-1 to 1010-n are implemented with foot switches (e.g., NFETs), the second network 1030 may be a ground network. In FIG. 10B, the label “Vdd/Gnd” indicates that the second network 1030 may be a power network or a ground network. The first network 1020 may also be referred to as a gated network. As used herein, a “gated network” is a network configured to be selectively power gated by one or more switches (e.g., the block switches 1010-1 to 1010-n).

It is to be appreciated that the layout of the second network 1030 shown in FIG. 10B is for illustrative purposes, and that the second network 1030 is not limited to a particular layout. For example, in certain aspects, the second network 1030 may include metal interconnects and vias stacked vertically (i.e., z direction) in the chip to couple the second network 1030 to bumps (not shown) on top of the chip, in which the bumps (e.g., solder bumps) are coupled to an external power source (e.g., power source 122) or an external ground.

As shown in FIG. 10B, the first network 1020 extends over the circuit block 115 to provide the circuit block 115 with power or ground. In the example shown in FIG. 10B, the first network 1020 includes a grid (also referred to as a mesh) including metal rails extending in the x direction and metal rails extending in the y direction, which is perpendicular to the x direction. The metals rail extending in the x direction and the metal rails extending in the y direction may be formed in different metal layers in the chip. In this example, the metal rails extending in the x direction may be coupled to the metal rails extending in the y direction by vias (not shown). It is to be appreciated that the first network 1020 is not limited to the exemplary layout shown in FIG. 10B.

In this example, the on/off states of the block switches 1010-1 to 1010-n may be controlled by a power manager (not shown) or a switch controller under the control of the power manager. For example, the power manager (not shown) may turn on the block switches 1010-1 to 1010-n when the circuit block 115 is active. The power manager may turn off the block switches 1010-1 to 1010-n when the circuit block 115 is inactive (i.e., not in use) to reduce leakage current.

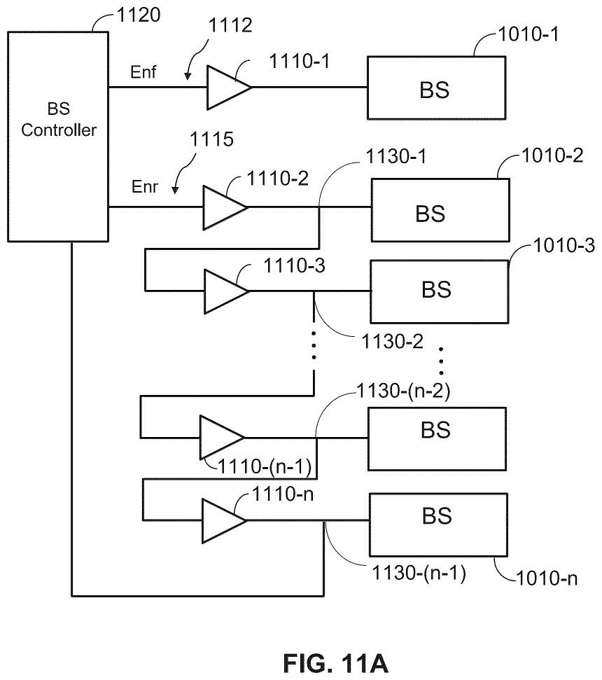

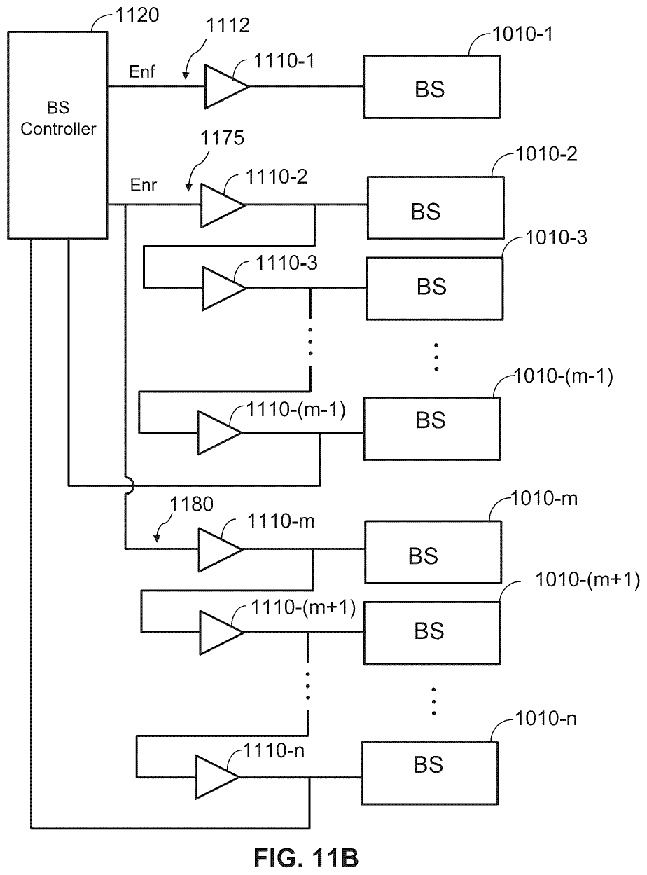

FIG. 11A shows an example of circuitry for enabling the block switches 1010-1 to 1010-n according to certain aspects. Note that the circuit block 115 and the networks 1020 and 1030 are not shown in FIG. 11A for case of illustration. Also, the block switches 1010-1 to 1010-n are shown arranged in a column in FIG. 11A for case of illustration (i.e., FIG. 11A is not intended to depict the physical layout of the block switches 1010-1 to 1010-n on the chip).

In this example, the circuitry includes a block switch controller 1120, a first enable path 1112, and a second enable path 1115. The block switch controller 1120 may be coupled to the power manager discussed above.

In this example, the block switch 1010-1 may be a high-resistance block switch and the block switches 1010-2 to 1010-n may be low-resistance block switches. As discussed further below, the high-resistance block switch is used to reduce inrush current when the circuit block 115 is powered up from a power collapsed state. A high-resistance block switch has a higher on resistance than a low-resistance block switch. As used herein, the “on resistance” of a switch is the resistance across the switch when the switch is turned on. For example, a low-resistance block switch may be implemented with a larger transistor than a high-resistance block switch to provide the low-resistance block switch with a lower on resistance. A high-resistance block switch may also be referred to as a few switch and a low-resistance switch may also be referred to as a rest switch. It is to be appreciated that the chip may include multiple high-resistance block switches at multiple locations on the periphery of the circuit block in some implementations.

In this example, the first enable path 1112 is coupled between the block switch controller 1120 and the block switch 1010-1. The first enable path 1112 may include a buffer 1110-1 to drive the block switch 1010-1. For the example where the block switch 1010-1 includes one or more transistors (e.g., one or more instances of the PFET 130 or one or more instances of the NFET 230), the first enable path 1112 is coupled between the block switch controller 1120 and the gates of the one or more transistors. The buffer 1110-1 may be inverting or non-inverting, and may include one or more inverters coupled in series.

In this example, the second enable path 1115 is coupled to the block switch controller 1120 and includes buffers 1110-2 to 1110-n coupled in series. Each of the buffers 1110-2 to 1110-n may include one or more inverters coupled in series. However, the buffers 1110-2 to 1110-n are not limited to this example.

In this example, the block switches 1010-2 to 1010-n are coupled to respective nodes 1130-1 to 1130-(n-1) (i.e., taps) on the second enable path 1115. In other words, the block switches 1010-2 to 1010-n are coupled to the second enable path 1115 in a daisy chain. In the example in FIG. 11A, the buffers 1110-2 to 1110-n are located between the nodes 1130-1 to 1130-(n-1) to generate delays between the nodes 1130-1 to 1130-(n-1). The delays between the nodes 1130-1 to 1130-(n-1) cause the block switches 1010-2 to 1010-n to sequentially turn on during power up, as discussed further below.

For the example where each of the block switches 1010-2 to 1010-n includes one or more transistors (e.g., one or more instances of the PFET 130 or one or more instances of the NFET 230), the gates of the one or more transistors of each of the block switches 1010-2 to 1010-n are coupled to the respective one of the nodes 1130-1 to 1130-(n-1) on the second enable path 1115.

To power up the circuit block 115 from a power collapsed state, the block switch controller 1120 may turn on the block switches 1010-1 to 1010-n in a sequence. For example, the block switch controller 1120 may first turn on the block switch 1010-1 by outputting a first enable signal Enf to the first enable path 1112. The first enable signal Enf may be low (e.g., ground potential) or high (e.g., Vdd) depending, for example, on whether the block switch 1010-1 is implemented with one or more PFETs or one or more NFETs. As discussed above, the block switch 1010-1 is a high-resistance switch (i.e., a few switch). The high resistance helps prevent a large inrush current from flowing into the circuit block 115, which may be power collapsed at the start of power up.

The turning on of the block switch 1010-1 causes the voltage of the circuit block 115 to ramp up. The voltage of the circuit block 115 eventually reaches a voltage that is high enough to prevent a large inrush current from flowing into the circuit block 115 when the block switches 1010-2 to 1010-n are turned on. At this point, the block switch controller 1120 may turn on the block switches 1010-2 to 1010-n (i.e., the rest switches) by outputting a second enable signal Enr to the second enable path 1115. The second enable signal Enr propagates through the second enable path 1115, causing the block switches 1010-2 to 1010-n to turn on. In this example, the delays between the nodes 1130-1 to 1130-(n-1) due to the buffers 1110-2 to 1110-n cause the block switches 1010-2 to 1010-n to sequentially turn on as the second enable signal Enr propagates through the second enable path 1115. The second enable signal Enr may be low (e.g., ground potential) or high (e.g., Vdd) depending, for example, on whether each of the block switches 1010-2 to 1010-n is implemented with one or more PFETs or one or more NFETs.

In certain aspects, the second enable path 1115 loops back to the block switch controller 1120, as shown in the example in FIG. 11A. This allows the block switch controller 1120 to detect when all of the block switches 1010-2 to 1010-n are turned on by detecting the return of the second enable signal Enr to the block switch controller 1120.

During power down, the block switch controller 1120 may turn off the block switches 1010-1 to 1010-n to power collapse the circuit block 115. For example, the block switch controller 1120 may turn off the block switches 1010-1 to 1010-n by outputting a logic state to the enable paths 1112 and 1115 that is the inverse of the logic state of the enable signals Enf and Enr used to turn on the block switches 1010-1 to 1010-n.

In certain aspects, subsets of the block switches 1010-2 to 1010-n may be turned on in parallel. In this regard, FIG. 11B shows an example in which the block switch controller 1120 outputs the second enable signal Enr to a second enable path 1175 and a third enable path 1180. The second enable path 1175 is coupled to the block switches 1010-2 to 1010-(m-1) in a daisy chain and includes the buffers 1110-2 to 1110-(m-1) coupled in series. The third enable path 1180 is coupled to the block switches 1010-m to 1010-n in a daisy chain and includes the buffers 1110-m to 1110-n coupled in series.

In this example, the second enable signal Enr propagates through the second enable path 1175 and the third enable path 1180 in parallel. This causes the block switches 1010-2 to 1010-(m-1) to sequentially turn on and the block switches 1010-m to 1010-n to sequentially turn on in parallel.

Thus, power gating for the circuit block 115 may be implemented using the block switches 1010-1 to 1010-n arranged along the periphery of the circuit block 115 or the globally distributed switches 310-1 to 310-k distributed in the circuit block 115. The block switches 1010-1 to 1010-n may reduce routing congestion over the circuit block 115 compared with the globally distributed switches 310-1 to 310-k, and the globally distributed switches 310-1 to 310-k may reduce IR drops in the power network and/or the ground network compared with the block switches 1010-1 to 1010-n, as discussed further below.

With regard to routing, the globally distributed switches 310-1 to 310-k may require routing over the circuit block 115 for both the first network 320 (i.e., the gated network) and the second network 330. This is because the globally distributed switches 310-1 to 310-k are distributed in the circuit block 115 and the second network 330 needs to extend over the circuit block 115 to reach the globally distributed switches 310-1 to 310-k. Also, the globally distributed switches 310-1 to 310-k may require metal routing over the circuit block 115 for the enable signals Enf and Enr discussed above.

In contrast, the block switches 1010-1 to 1010-n are located along the periphery of the circuit block 115, which may allow the second network 1030 to reach the block switches 1010-1 to 1010-n without extending over the circuit block 115 or extending only over a small portion of the circuit block 115 close to the periphery. As a result, using the block switches 1010-1 to 310-n may significantly reduce or eliminate routing of the second network 1030 over the circuit block 115. The block switches 1010-1 to 1010-n may also reduce the area of the circuit block 115 since the block switches 1010-1 to 1010-n do not require areas distributed throughout the circuit block 115 for placement of the block switches 1010-1 to 1010-n. Thus, the block switches 1010-1 to 1010-n may be used to reduce routing congestion and area compared with the globally distributed switches 310-1 to 310-k.

With regard to IR drops, the globally distributed switches 310-1 to 310-k may reduce IR drops compared with the block switches 1010-1 to 1010-n. This is because the globally distributed switches 310-1 to 310-k are distributed in the circuit block 115. As a result, the distances currents need to flow in the first network 320 between the globally distributed switches 310-1 to 310-k and active devices in the circuit block 115 may be relatively short, resulting in lower IR drops in the first network 320.

In contrast, currents may need to flow in the first network 1020 over longer distances to reach active devices in the circuit block 115 since the block switches 1010-1 to 1010-n are located on the periphery of the circuit block 115. The longer distances currents need to travel in the first network 1020 (especially for active devices located at or near the center of the circuit block 115) increase IR drops in the first network 1020, resulting in lower operating voltages within the circuit block 115. Thus, the globally distributed switches 310-1 to 310-k may be used to reduce IR drops compared with the block switches 1010-1 to 1010-n.

Therefore, the block switches 1010-1 to 1010-n and the globally distributed switches 310-1 to 310-k provide tradeoffs between routing congestion, area, and IR drops. The block switches 1010-1 to 1010-n may be used to reduce routing congestion and area at the expense of higher IR drops while the globally distributed switches 310-1 to 310-k may be used to reduce IR drops for higher operating voltages within the circuit block 115 at the expense of higher routing congestion over the circuit block 115 and area.

To exploit the advantages of both the block switches 1010-1 to 1010-n and the globally distributed switches 310-1 to 310-k, aspects of the present disclosure provide a hybrid power gating scheme using both the block switches 1010-1 to 1010-n and the globally distributed switches 310-1 to 310-k. The hybrid power gating scheme may provide improved IR drops compared with a power gating scheme using all block switches, and provide less routing congestion and reduced area compared with a power gating scheme using all globally distributed switches. The hybrid power gating scheme may be used for process nodes that offer both block switches and globally distributed switches. The above features and other features of the present disclosure are discussed further below.

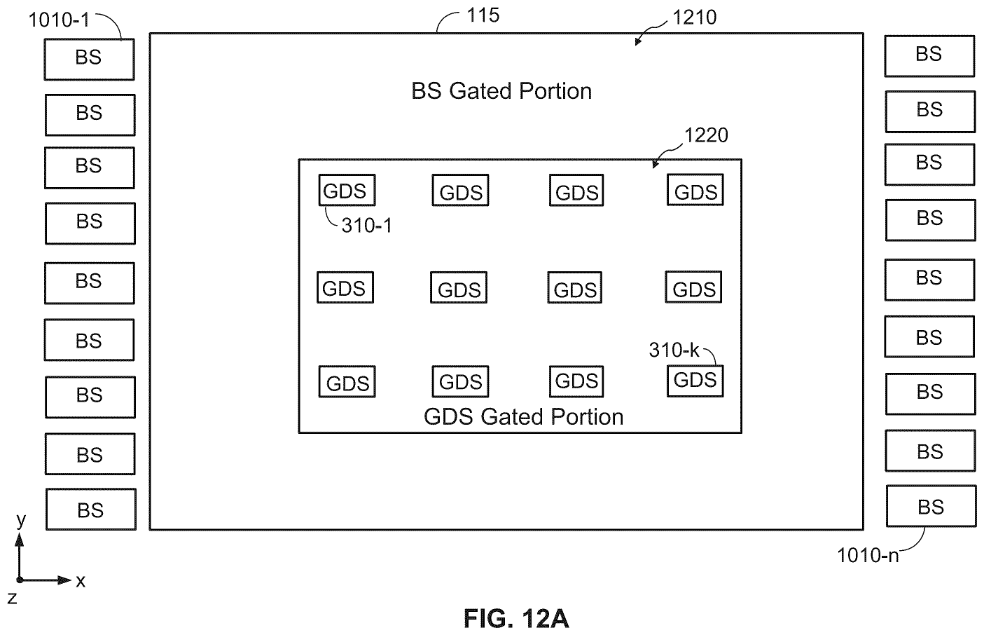

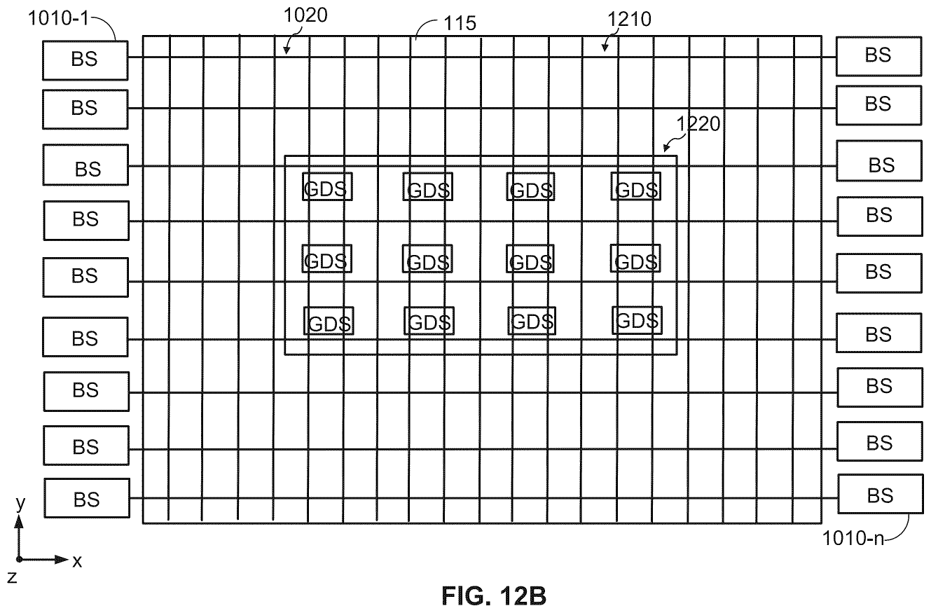

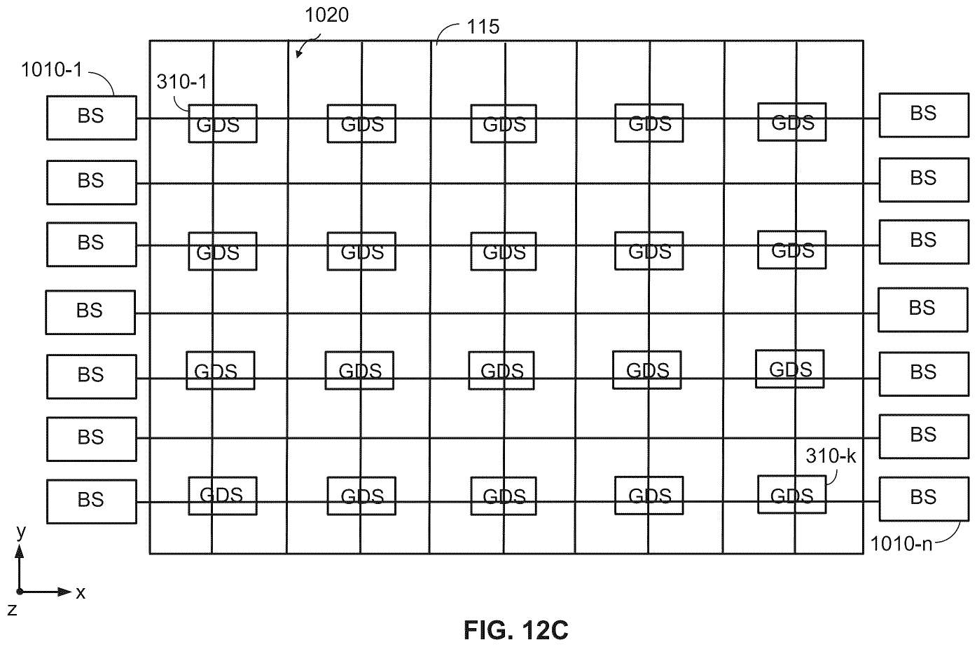

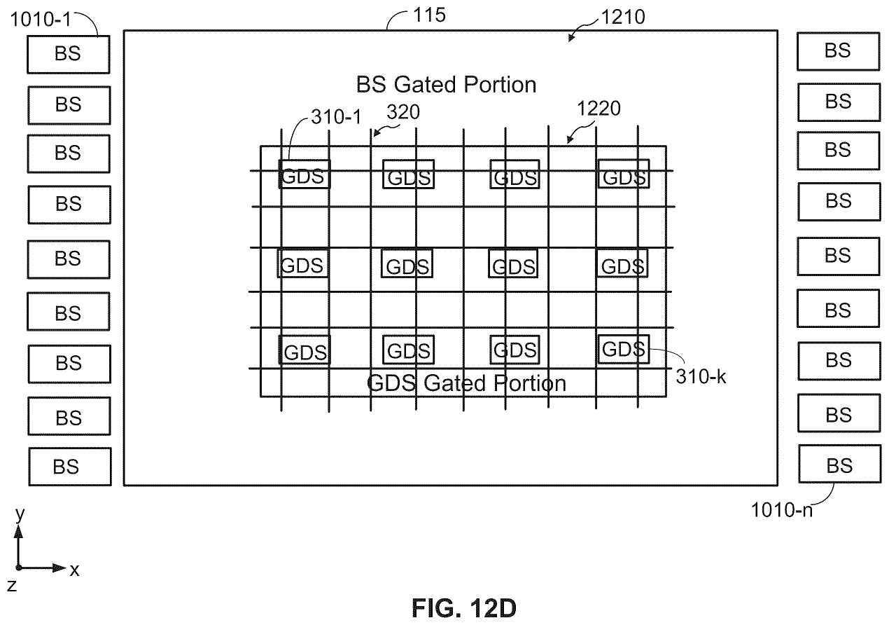

FIG. 12A is a top view illustrating an exemplary hybrid power gating scheme according to certain aspects of the present disclosure. In this example, the chip includes the block switches 1010-1 to 1010-n arranged along the periphery of the circuit block 115 to provide block switch power gating to a first portion 1210 according to certain aspects. The first portion 1210 may also be referred to as the block switch (BS) gated portion. In this example, the first network 1020 (shown in FIG. 10B) coupled to the block switches 1010-1 to 1010-n extends over the first portion 1210 of the circuit block 115.

The block switches 1010-1 to 1010-n may be implemented with head switches (i.e., block head switches) or foot switches, as discussed above. It is to be appreciated that the chip may include a smaller or larger number of the block switches 1010-1 to 1010-n than shown in the example in FIG. 12A. Although FIG. 12A shows an example in which the block switches 1010-1 to 1010-n are arranged along the left boundary and the right boundary of the circuit block 115, it is to be appreciated that the block switches 1010-1 to 1010-n may also be arranged along the top boundary and/or the bottom boundary of the circuit block 115. As discussed above, the circuit block 115 is not limited to a particular shape. Accordingly, the circuit block 115 is not limited to the exemplary shape shown in FIG. 12A.

In this example, the chip also includes the globally distributed switches 310-1 to 310-k distributed within a second portion 1220 (i.e., second area) of the circuit block 115 to provide globally distributed switch power gating according to certain aspects. The second portion 1220 may also be referred to as the globally distributed switch (GDS) gated portion. In the example shown in FIG. 12A, the first portion 1210 (i.e., first area) of the circuit block 115 surrounds the second portion 1220 (i.e., second area) of the circuit block 115. However, it is to be appreciated that this need not be the case in other implementations.

The globally distributed switches 310-1 to 310-k may be implemented with head switches (i.e., block head switches) or foot switches, as discussed above. It is to be appreciated that the chip may include a smaller or larger number of the globally distributed switches 310-1 to 310-k than shown in the example in FIG. 12A. It is to be appreciated that the globally distributed switches 310-1 to 310-k are not limited to the exemplary distribution pattern shown in FIG. 12A.

FIG. 12B shows an example in which the first network 1020 (shown in FIG. 10B) extends over the second portion 1220 of the circuit block 115. In this example, the globally distributed switches 310-1 to 310-k may be coupled between the second network 330 (shown in FIG. 3C) and the first network 1020. In this example, the portion of the first network 1020 extending over the second portion 1220 of the circuit block 115 implements the first network 320 shown in FIG. 3B. In other words, the first network 320 for the globally distributed switches 310-1 to 310-k may be merged with the first network 1020 for the block switches 1010-1 to 1010-n to provide a shared gated network for the block switches 1010-1 to 1010-n and the globally distributed switches 310-1 to 310-k. In this example, the globally distributed switches 310-1 to 310-k may be used to pull up the voltages of the network 1020 over the second portion 1220.

It is to be appreciated that the present disclosure is not limited to the relative sizes of the first portion 1210 and the second portion 1220 shown in the example in FIGS. 12A and 12B. For example, various combinations of the 1010-1 to 1010-n and the globally distributed switches 310-1 to 310-k can be used (e.g., depending on a desired tradeoff between area and IR drops). For example, the first portion 1210 may be increased relative to the second portion 1220 to provide a larger area savings, or the second portion 1220 may be increased relative to the first portion 1210 to reduce IR drops and increase operating voltages (which can support higher frequencies).

FIG. 12C is a top view illustrating another exemplary hybrid power gating scheme according to certain aspects of the present disclosure. In this example, the globally distributed switches 310-1 to 310-k are distributed throughout the circuit block 115, and the globally distributed switches 310-1 to 310-k and the block switches 1010-1 to 1010-n share the first network 1020 (which is the gated network in this example). In this example, distributing the globally distributed switches 310-1 to 310-k throughout the circuit block 115 allows the rails of the first network 1020 to be spaced farther apart compared with the spacing between the rails in the example in FIG. 12B. This is because the globally distributed switches 310-1 to 310-k pull up the voltages on the first network 1020, which allows the network 1020 to provide a desired voltage throughout the circuit block 115 with a smaller number of rails spaced father apart. The larger spacing between the rails relaxes the bump pitch for the block switches 1010-1 to 1010-n.

In some implementations, the globally distributed switches 310-1 to 310-k and the block switches 1010-1 to 1010-n may be coupled to independent gated networks instead of a shared gated network. In this regard, FIG. 12D shows an example in which the globally distributed switches 310-1 to 310-k are coupled to the first network 320, which is independent of the first network 1020 for the block switches 1010-1 to 1010-n in this example. For case of illustration, the first network 1020 is not shown in FIG. 12D in order to not obscure the first network 320. In this example, the block switches 1010-1 to 1010-n may be coupled between the second network 1030 and the first network 1020, and the globally distributed switches 310-1 to 310-k may be coupled between the second network 330 and the first network 320.

In certain aspects, the power gating design of the circuit block 115 may initially start with all block switches. In this example, hotpots may be determined in the circuit block 115 using a computer simulation and/or a test chip. The hotpots may be determined by determining areas with higher current densities, higher switching activity, and/or lower operating voltages. After the hotspots are determined, the globally distributed switches 310-1 to 310-k may be added to the power gating design to cover the determined hotspots. Thus, the size, shape, and/or location of the second portion 1220 (i.e., second arca) may be chosen to cover the determined hotspots in the circuit block 115. The addition of the globally distributed switches 310-1 to 310-k may significantly improve performance compared with the initial power gating design using all block switches.

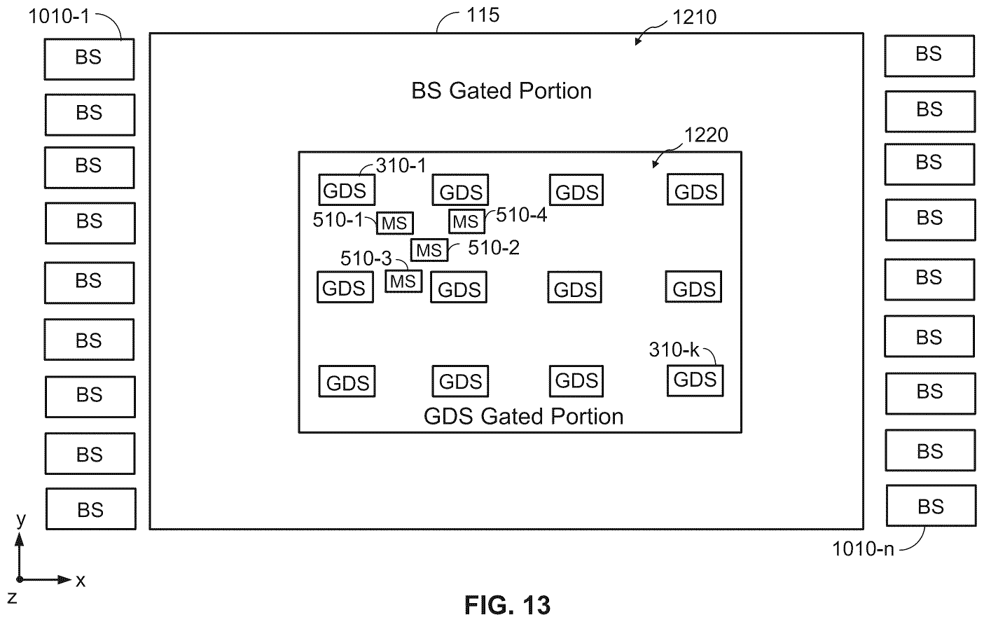

In certain aspects, the chip may also include the micro switches 510-1 to 510-4 in the second portion 1220 of the circuit block 115. In this regard, FIG. 13 shows an example in which the chip includes the micro switches 510-1 to 510-4 sprinkled between the globally distributed switches in the second portion 1220 of the circuit block 115. It is to be appreciated that the chip may include additional micro switches (not shown) sprinkled in other areas of the second portion 1220 of the circuit block 115.

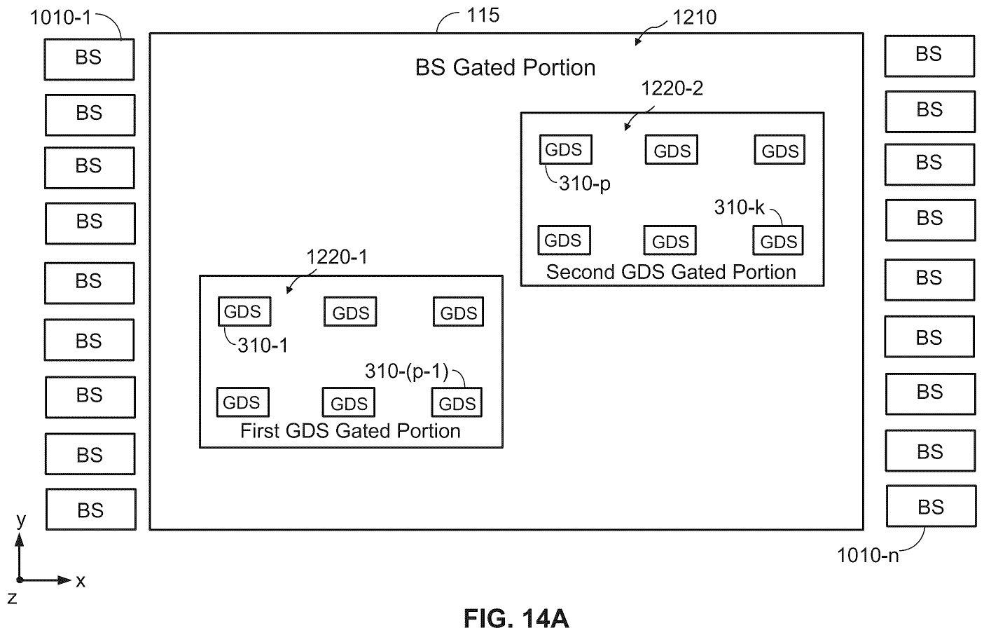

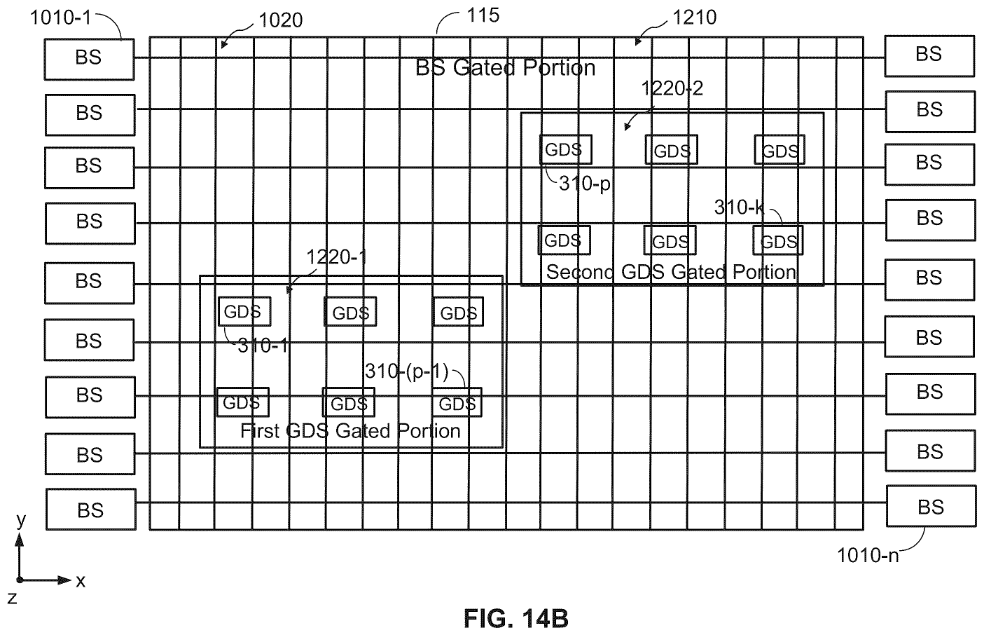

It is to be appreciated that the second portion 1220 of the circuit block 115 need not be contiguous. In this regard, FIG. 14A shows an example in which the second portion 1420 of the circuit block 115 in FIGS. 12A, 12B, FIG. 12D, and 13 is split into two non-contiguous portions 1220-1 to 1220-2. In this example, a first subset of the globally distributed switches 310-1 to 310-(p-1) are distributed in the portion 1220-1 and a second subset of the globally distributed switches 310-p to 310-k are distributed in the portion 1220-2 where p is less than k.

Although the portions 1220-1 and 1220-2 are shown having the same shape and size in the example in FIG. 14A, it is to be appreciated that, in other examples, the portions 1220-1 and 1220-2 may have different shapes and/or sizes (e.g., depending on the locations of hotspots in the circuit block 115). It is also to be appreciated that the second portion 1220 may be split into three or more non-contiguous portions in other examples. It is to be appreciated that micro switches (not shown in FIG. 13) may be sprinkled in the portion 1220-1, the portion 1220-2, or both portions 1220-1 and 1220-2 in some examples.

FIG. 14B shows an example in which the globally distributed switches 310-1 to 310-k and the block switches 1010-1 to 1010-n share a gated network (e.g., the first network 1020) according to certain aspects of the present disclosure. In this example, the block switches 1010-1 to 1010-n may be coupled between the second network 1030 and the first network 1020, and the globally distributed switches 310-1 to 310-k may be coupled between the second network 330 and the first network 1020. In this example, the first network 1020 (i.e., the shared gated network in this example) may be powered by turning on the globally distributed switches 310-1 to 310-k, turning on the block switches 1010-1 to 1010-n, or turning on both the globally distributed switches 310-1 to 310-k and the block switches 1010-1 to 1010-n. In other implementations, the globally distributed switches 310-1 to 310-k and the block switches 1010-1 to 1010-n may have independent gated networks.

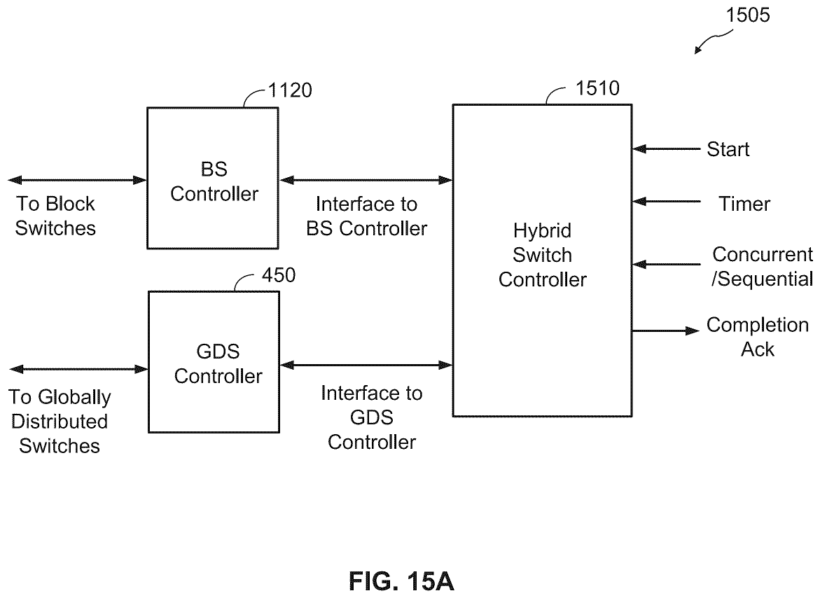

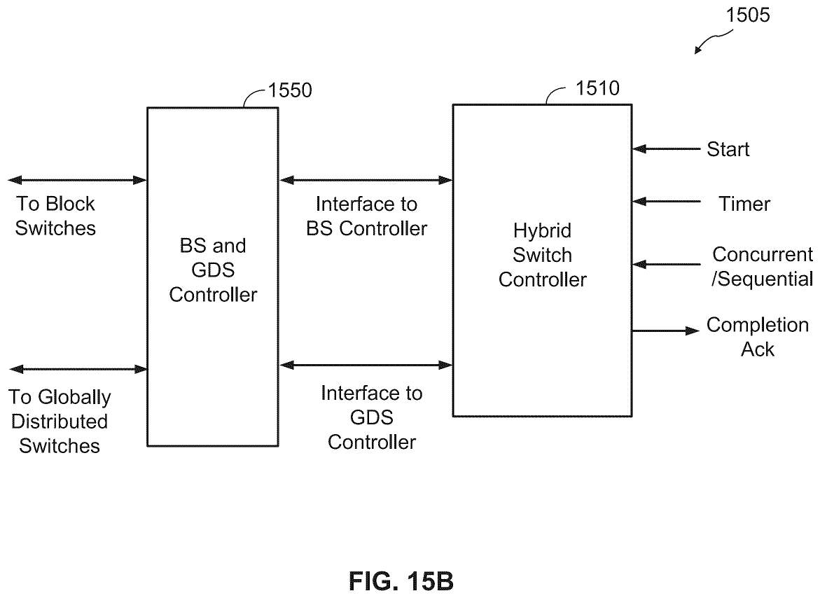

FIG. 15A shows an example of a hybrid power gating control circuit 1505 for controlling the block switches 1010-1 to 1010-n and the globally distributed switches 310-1 to 310-k in the hybrid power gating scheme according to certain aspects. In this example, the hybrid power gating control circuit 1505 includes block switch controller 1120 discussed above for controlling the block switches 1010-1 to 1010-n and the globally distributed switch controller 450 discussed above for controlling the globally distributed switches 310-1 to 310-k. The hybrid power gating control circuit 1505 also includes a hybrid switch controller 1510 coupled to the block switch controller 1120 and the globally distributed switch controller 450. Each of the controllers 1120, 450, and 1510 may be implemented with a processor, gated logic, a field programmable gate array (FPGA), programmable logic devices (PLDs), discrete hardware circuits, and/or any combination thereof.

In certain aspects, the hybrid switch controller 1510 is configured to control the block switch controller 1120 and the globally distributed switch controller 450 to coordinate the switching of the block switches 1010-1 to 1010-n and the globally distributed switches 310-1 to 310-k, as discussed further below.

For example, the hybrid switch controller 1510 may be configured to turn on only the block switches 1010-1 to 1010-n in a first mode, and turn on both the block switches 1010-1 to 1010-n and the globally distributed switches 310-1 to 310-k in a second mode. In this example, in the first mode, the hybrid switch controller 1510 may instruct the block switch controller 1120 to turn on the block switches 1010-1 to 1010-n without instructing the globally distributed switch controller 450 to turn on the globally distributed switches 310-1 to 310-k. In this mode, the second portion 1220 of the circuit block 115 may receive power from the block switches 1010-1 to 1010-n through the network 1020 (which may be a shared gated network for both portions 1210 and 1220 in the example in FIG. 12B). For example, the first mode may be used when the circuit block 115 is operating at a lower frequency and may tolerate lower operating voltages within the second portion 1220.

In the second mode, the hybrid switch controller 1510 also instructs the globally distributed switch controller 450 to turn on the globally distributed switches 310-1 to 310-k. For example, the hybrid switch controller 1410 may turn on the globally distributed switches 310-1 to 310-k in the second mode when the circuit block 115 is operating at a higher frequency and needs the operating voltages within the second portion 1220 to be pulled up by the globally distributed switches 310-1 to 310-k, or based on power distribution weakness feedback due to limitations of the block switches 1010-1 to 1010-n.

In certain aspects, during power up of the circuit block 115 in the second mode, the hybrid switch controller 1510 may turn on the block switches 1010-1 to 1010-n and the globally distributed switches 310-1 to 310-k in response to a start signal from the power manager. In this example, the hybrid switch controller 1510 may turn on the block switches 1010-1 to 1010-n and the globally distributed switches 310-1 to 310-k concurrently or sequentially (e.g., based on a signal from the power manager indicating concurrent or sequential activation of the block switches 1010-1 to 1010-n and the globally distributed switches 310-1 to 310-k).

To concurrently turn on the block switches 1010-1 to 1010-n and the globally distributed switches 310-1 to 310-k, the hybrid switch controller 1410 may concurrently instruct the block switch controller 1120 to turn on the block switches 1010-1 to 1010-n and the globally distributed switch controller 450 to turn on the globally distributed switches 310-1 to 310-k.

To sequentially turn on the block switches 1010-1 to 1010-n and the globally distributed switches 310-1 to 310-k, the hybrid switch controller 1510 may first instruct the block switch controller 1120 to turn on the block switches 1010-1 to 1010-n. After a time delay, the hybrid switch controller 1510 may instruct the globally distributed switch controller 450 to turn on the globally distributed switches 310-1 to 310-k. In some implementations, the hybrid switch controller 1510 may receive a timer signal specifying the time delay from the power manager, and set the time delay based on the received timer signal. For the case where the block switches 1010-1 to 1010-n are turned on first, the high-resistance switches 410-1 to 410-k may be omitted from the globally distributed switches 310-1 to 310-k.

In certain aspects, the hybrid switch controller 1510 may send a completion acknowledgement signal to the power manager when the block switches 1010-1 to 1010-n have been turned on in the first mode or when both the block switches 1010-1 to 1010-n and the globally distributed switches 310-1 to 310-k have been turned on in the second mode.

FIG. 15B shows an example in which the block switch controller 1120 and the globally distributed switch controller 450 are integrated into a block switch and globally distributed switch controller 1550 that can control both the block switches 1010-1 to 1010-n and the globally distributed switches 310-1 to 310-k.

Implementation examples are described in the following numbered clauses:

1. A chip, comprising:
a circuit block;
globally distributed switches physically located in the circuit block; and
micro switches distributed between at least two of the globally distributed switches in the circuit block.

2. The chip of clause 1, wherein a minimum spacing between the micro switches is less than a minimum spacing between the globally distributed switches.

3. The chip of clause 1 or 2, wherein the micro switches are distributed nonuniformly.

4. The chip of any one of clauses 1 to 3, wherein each of the micro switches is at least two times smaller than each of the globally distributed switches.

5. The chip of any one of clauses 1 to 4, further comprising an enable path, wherein the globally distributed switches are coupled to the enable path, the enable path includes buffers, and the micro switches are coupled to the enable path between the at least two of the globally distributed switches.

6. The chip of clause 5, wherein the micro switches are coupled to the enable path in a star configuration.

7. The chip of clause 5, wherein the micro switches are coupled to the enable path in a daisy chain configuration.

8. The chip of any one of clauses 5 to 7, wherein each of the buffers comprises one or more inverters coupled in series.

9. The chip of any one of clauses 5 to 8, further comprising a switch controller coupled to the enable path, wherein the switch controller is configured to output an enable signal to the enable path to turn on the globally distributed switches and the micro switches.

10. The chip of clause 9, wherein the enable signal sequentially turns on the globally distributed switches as the enable signal propagates through the enable path.

11. The chip of any one of clauses 1 to 10, wherein the globally distributed switches include low-resistance switches and high-resistance switches, each of the high-resistance switches having a higher on resistance than each of the low-resistance switches, and the chip further comprises:
a first enable path, wherein the high-resistance switches are coupled to the first enable path, and the first enable path includes first buffers; and
a second enable path, wherein the low-resistance switches are coupled to the second enable path, the second enable path includes second buffers, and the micro switches are coupled to the second enable path between at least two of the low-resistance switches.

12. The chip of clause 11, wherein the micro switches are coupled to the second enable path in a star configuration.

13. The chip of clause 11, wherein the micro switches are coupled to the second enable path in a daisy chain configuration.

14. The chip of any one of clauses 11 to 13, further comprising a switch controller coupled to the first enable path and the second enable, wherein the switch controller is configured to:
output a first enable signal to the first enable path to turn on the high-resistance switches; and
after a time delay from outputting the first enable signal, output a second enable signal to the second enable path to turn on the low-resistance switches and the micro switches.

15. The chip of any one of clauses 11 to 14, wherein the micro switches are distributed nonuniformly.

16. The chip of any one of clauses 11 to 15, wherein each of the micro switches is at least two times smaller than each of the globally distributed switches.

17. The chip of any one of clauses 1 to 16, further comprising:
block switches arranged along at least part of a periphery of the circuit block; and
a gated network coupled to the block switches and the circuit block.

18. The chip of clause 17, wherein the globally distributed switches are coupled to the gated network.

19. The chip of clause 17 or 18, further comprising a hybrid switch controller coupled to the block switches and the globally distributed switches, wherein the hybrid switch controller is configured to turn on the block switches and the globally distributed switches sequentially or turn on the block switches and the globally distributed switches concurrently.

20. The chip of clause 17 or 18, further comprising a hybrid switch controller coupled to the block switches and the globally distributed switches, wherein the hybrid switch controller is configured to turn on the block switches, and turn on the globally distributed switches after a time delay from turning on the block switches.

21. The chip of any one of clauses 17 to 20, further comprising a first power network, wherein each of the block switches is coupled between the first power network and the gated network.

22. The chip of clause 21, further comprising a second power network, wherein each of the globally distributed switches is coupled between the second power network and the gated network.

23. The chip of any one of clauses 17 to 22, wherein the circuit block comprises a processor.

24. The chip of any one of clauses 17 to 23, wherein the gated network comprises first metal rails extending in a first direction, and second metal rails extending in a second direction perpendicular to the first direction.

25. The chip of any one of clauses 1 to 16, further comprising:
block switches arranged along at least part of a periphery of the circuit block;
a first gated network coupled to the block switches and the circuit block; and
a second gated network coupled to the globally distributed switches and the circuit block.

26. The chip of clause 25, further comprising a first power network, wherein each of the block switches is coupled between the first power network and the first gated network.

27. The chip of clause 26, further comprising a second power network, wherein each of the globally distributed switches is coupled between the second power network and the second gated network.

28. The chip of any one of clauses 25 to 27, further comprising a hybrid switch controller coupled to the block switches and the globally distributed switches, wherein the hybrid switch controller is configured to turn on the block switches and the globally distributed switches sequentially or turn on the block switches and the globally distributed switches concurrently.

29. The chip of any one of clauses 25 to 27, further comprising a hybrid switch controller coupled to the block switches and the globally distributed switches, wherein the hybrid switch controller is configured to turn on the block switches, and turn on the globally distributed switches after a time delay from turning on the block switches.

30. The chip of any one of clauses 1 to 29, wherein the circuit block comprises standard cells, and the micro switches are distributed between at least two of the standard cells.

31. A chip, comprising:
a circuit block;
block switches arranged along at least part of a periphery of the circuit block;
globally distributed switches physically located in the circuit block; and
a gated network coupled to the circuit block, the block switches, and the globally distributed switches.

32. The chip of clause 31, further comprising a hybrid switch controller coupled to the block switches and the globally distributed switches, wherein the hybrid switch controller is configured to turn on the block switches and the globally distributed switches sequentially or turn on the block switches and the globally distributed switches concurrently.

33. The chip of clause 31, further comprising a hybrid switch controller coupled to the block switches and the globally distributed switches, wherein the hybrid switch controller is configured to turn on the block switches, and turn on the globally distributed switches after a time delay from turning on the block switches.

34. The chip of any one of clauses 31 to 33, further comprising:
a first power network, wherein each of the block switches is coupled between the first power network and the gated network; and
a second power network, wherein each of the globally distributed switches is coupled between the second power network and the gated network.

35. A chip, comprising:
a circuit block;
block switches arranged along at least part of a periphery of the circuit block;
globally distributed switches physically located in the circuit block;
a first gated network coupled to the circuit block and the block switches; and
a second gated network coupled to the circuit block and the globally distributed switches.

36. The chip of clause 35, further comprising a hybrid switch controller coupled to the block switches and the globally distributed switches, wherein the hybrid switch controller is configured to turn on the block switches and the globally distributed switches sequentially or turn on the block switches and the globally distributed switches concurrently.

37. The chip of clause 35, further comprising a hybrid switch controller coupled to the block switches and the globally distributed switches, wherein the hybrid switch controller is configured to turn on the block switches, and turn on the globally distributed switches after a time delay from turning on the block switches.

38. The chip of any one of clauses 35 to 37, further comprising:
a first power network, wherein each of the block switches is coupled between the first power network and the first gated network; and
a second power network, wherein each of the globally distributed switches is coupled between the second power network and the second gated network.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a circuit block;
globally distributed switches physically located in the circuit block; and
micro switches distributed between at least two of the globally distributed switches in the circuit block.

2. The chip of claim 1, wherein a minimum spacing between the micro switches is less than a minimum spacing between the globally distributed switches.

3. The chip of claim 1, wherein the micro switches are distributed nonuniformly.

4. The chip of claim 1, wherein each of the micro switches is at least two times smaller than each of the globally distributed switches.

5. The chip of claim 1, further comprising an enable path, wherein the globally distributed switches are coupled to the enable path, the enable path includes buffers, and the micro switches are coupled to the enable path between the at least two of the globally distributed switches.

6. The chip of claim 5, wherein the micro switches are coupled to the enable path in a star configuration.

7. The chip of claim 5, wherein the micro switches are coupled to the enable path in a daisy chain configuration.

8. The chip of claim 5, wherein each of the buffers comprises one or more inverters coupled in series.

9. The chip of claim 5, further comprising a switch controller coupled to the enable path, wherein the switch controller is configured to output an enable signal to the enable path to turn on the globally distributed switches and the micro switches.

10. The chip of claim 9, wherein the enable signal sequentially turns on the globally distributed switches as the enable signal propagates through the enable path.

11. The chip of claim 1, wherein the globally distributed switches include low-resistance switches and high-resistance switches, each of the high-resistance switches having a higher on resistance than each of the low-resistance switches, and the chip further comprises:
a first enable path, wherein the high-resistance switches are coupled to the first enable path, and the first enable path includes first buffers; and
a second enable path, wherein the low-resistance switches are coupled to the second enable path, the second enable path includes second buffers, and the micro switches are coupled to the second enable path between at least two of the low-resistance switches.

12. The chip of claim 11, wherein the micro switches are coupled to the second enable path in a star configuration.

13. The chip of claim 11, wherein the micro switches are coupled to the second enable path in a daisy chain configuration.

14. The chip of claim 11, further comprising a switch controller coupled to the first enable path and the second enable, wherein the switch controller is configured to:
output a first enable signal to the first enable path to turn on the high-resistance switches; and
after a time delay from outputting the first enable signal, output a second enable signal to the second enable path to turn on the low-resistance switches and the micro switches.

15. The chip of claim 11, wherein the micro switches are distributed nonuniformly.

16. The chip of claim 11, wherein each of the micro switches is at least two times smaller than each of the globally distributed switches.

17. The chip of claim 1, further comprising:
block switches arranged along at least part of a periphery of the circuit block; and
a gated network coupled to the block switches and the circuit block.

18. The chip of claim 17, further comprising a hybrid switch controller coupled to the block switches and the globally distributed switches, wherein the hybrid switch controller is configured to turn on the block switches and the globally distributed switches sequentially or turn on the block switches and the globally distributed switches concurrently.

19. The chip of claim 17, further comprising a hybrid switch controller coupled to the block switches and the globally distributed switches, wherein the hybrid switch controller is configured to turn on the block switches, and turn on the globally distributed switches after a time delay from turning on the block switches.

20. The chip of claim 1, further comprising:
block switches arranged along at least part of a periphery of the circuit block;
a first gated network coupled to the block switches and the circuit block; and
a second gated network coupled to the globally distributed switches and the circuit block.
